(19) United States
(12) Patent Application Publication
(10) Pub. No.: US 2011/0062454 A1
(43) Pub. Date: Mar. 17, 2011

(54) LIGHT EMITTING DEVICE HAVING REMOTELY LOCATED LIGHT SCATTERING MATERIAL

(75) Inventors: Shan Mei Wan, Shatin (HK); Ming Lu, Sijhih City (TW)

(73) Assignee: Hong Kong Applied Science and Technology Research Institute Co., Ltd., Shatin (HK)

(21) Appl. No.: 12/558,166

(22) Filed: Sep. 11, 2009

(51) Int. Cl. H01L 33/00

(52) U.S. Cl. 257/88; 257/98; 257/E33.074

(57) ABSTRACT

A light emitting device with a remotely located light scattering material which improves color mixing property is provided. The light emitting device includes a substrate defining a cavity; one or more light emitting elements bonded to the substrate and positioned in the cavity; at least one first layer covering the one or more light emitting elements, at least part of the at least one first layer within the cavity, wherein the at least one first layer has a refractive index less than the refractive index of the one or more light emitting elements; and at least one second layer including light scattering material disposed on the at least one first layer, wherein the refractive index of the first layer is less than or equal to the refractive index of the second layer.

### FIELD OF THE INVENTION

The present invention relates to a light emitting device, and more particularly, to a light emitting device having remotely located light scattering material.

### BACKGROUND OF THE INVENTION

Light emitting diodes (hereinafter referred to as “LEDs”) is currently one of the most innovative and fastest growing technologies in the semiconductor industry. While LEDs have been in use for decades as indicators and for signaling purposes, technology developments and improvements have allowed for a broader use of LEDs in illumination applications.

The use of LEDs in illumination applications is attractive for a number of reasons, including the ability to produce more light per watt, longer lifetime, smaller size, greater durability, environmental friendliness and flexibility in terms of coloring, beam control and dimming. In addition, many efforts have been made to produce white light sources, such as phosphor converted white light devices, using different kinds of phosphors, like yellow, green, blue or red phosphors. Another method of producing white light sources is by using red, blue and green LEDs. However, these and other methods face the challenge of providing an evenly distributed light and/or color mixing in a device having a relatively small area. Providing evenly distributed light and achieving sufficient color mixing can be difficult because different colors of light have a different light spectrum and they each exhibit different optical properties, like reflection and refraction. While currently known methods have attempted to generate a uniform light distribution and solve these and other problems, such methods have not been fully satisfactory.

Accordingly, there is a need for a light emitting device having remotely located light scattering material that addresses the above shortcoming.

### SUMMARY OF THE INVENTION

According to one embodiment of the present invention, a light emitting device having remotely located light scattering material is disclosed. The light emitting device includes a substrate defining a cavity; one or more light emitting elements bonded to the substrate, the one or more light emitting elements positioned in the cavity, the one or more light emitting elements configured to emit light; at least one first layer covering the one or more light emitting elements, at least part of the at least one first layer within the cavity, the at least one first layer having an upper surface, wherein the at least one first layer has a refractive index less than the refractive index of the one or more light emitting elements; and at least one second layer disposed on the at least one first layer, the at least one second layer including light scattering material, wherein the refractive index of the at least one second layer is less than the refractive index of the one or more light emitting elements, and the refractive index of the first layer is less than or equal to the refractive index of the second layer.

According to another embodiment of the present invention, a light emitting device having remotely located light scattering material is disclosed. The light emitting device includes a substrate; one or more light emitting elements bonded onto the substrate; at least one first layer covering the one or more light emitting elements on the substrate, the at least one first layer having an upper surface and side surfaces; and at least one second layer covering the at least one first layer, the at least one second layer including light scattering material, wherein the refractive index of the at least one second layer is less than the refractive index of the one or more light emitting elements, and the refractive index of the first layer is less than or equal to the refractive index of the second layer.

Still other embodiments of the present invention will become readily apparent to those skilled in the art from the following detailed description, wherein embodiments of the invention are described by way of illustration. As will be realized, the invention is capable of other and different embodiments and its several details are capable of modifications in various respects, all without departing from the spirit and the scope of the present invention.

### BRIEF DESCRIPTION OF THE DRAWINGS

FIG. 1 is a cross sectional view of a light emitting device, in accordance with a first embodiment of the present invention.

FIG. 2 is a cross sectional view of a light emitting device, in accordance with a second embodiment of the present invention.

FIG. 2A is a partial top view of the light emitting device shown in FIG. 2, in accordance with a second embodiment of the present invention.

FIG. 2B is a partial, side cross sectional view top view of the first layer shown in FIG. 3, in accordance with a second embodiment of the present invention.

FIG. 3 is a cross sectional view of a light emitting device, in accordance with a third embodiment of the present invention.

FIG. 4 is a cross sectional view of a light emitting device, in accordance with a fourth embodiment of the present invention.

FIG. 4A is a partial top view of the light emitting device shown in FIG. 3, in accordance with a fourth embodiment of the present invention.

FIG. 4B is a partial, side cross sectional view top view of the first layer shown in FIG. 3, in accordance with a fourth embodiment of the present invention.

FIG. 5 is a cross sectional view of a light emitting device, in accordance with a fifth embodiment of the present invention.

### DETAILED DESCRIPTION

In the following description, reference is made to the accompanying drawings where, by way of illustration, specific embodiments of the invention are shown. It is to be understood that other embodiments may be used as structural and other changes may be made without departing from the scope of the present invention. Also, the various embodiments and aspects from each of the various embodiments may be used in any suitable combinations. Accordingly, the drawings and detailed description are to be regarded as illustrative in nature but not as restrictive.

Generally, embodiments of the present invention are directed to a light emitting device having remotely located light scattering material.

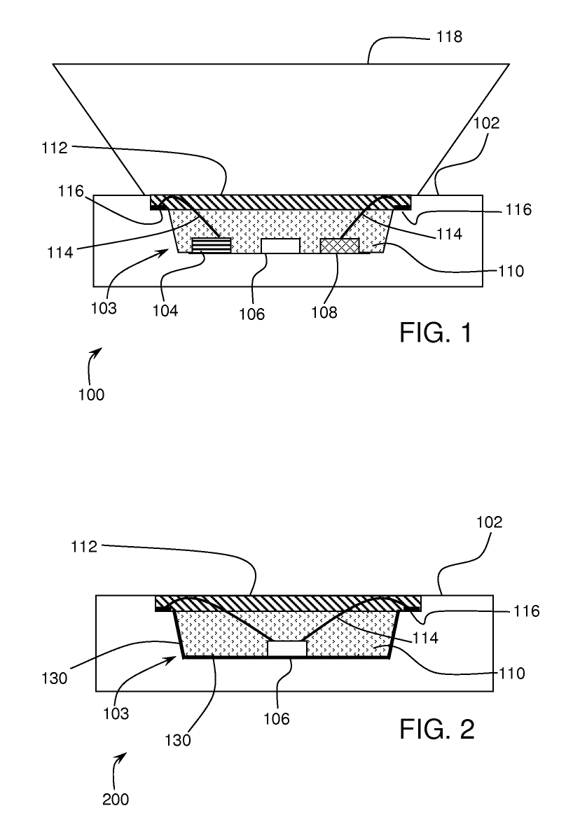

FIG. 1 is a cross sectional view of a light emitting device, in accordance with a first embodiment of the present invention. The light emitting device 100 includes a substrate 102 and a red LED 104, a blue LED 106, and a green LED 108 bonded onto a cavity 103 formed in the substrate 102. A first layer 110 is filled into the optical cavity 103 and disposed on top of or surrounding the red LED 104, the blue LED 106, and the green LED 108 (collectively refer to as “the RBG LEDs”). A second layer 112 is disposed on top of or surrounding the first layer 11 0. According to embodiments of the present invention, the second layer 112 includes light scattering material. According to one embodiment of the present invention, the light scattering material includes a plurality of particles configured to scatter light emitted by the RBG LEDs. Contact wires 114 may electrically connect each of the RBG LEDs to metal contacts 116. First or secondary optics 118, such as a lens or a reflector, may also be provided on top of the second layer 112 for directing or reflecting the light. According to one embodiment, the first and second layers are transparent and insulating. However, according to other embodiments, the first and second layers may be partially transparent or translucent.

According to the illustrated embodiment, the first layer 110 alters the light rays emitted from the RBG LEDs before it is transmitted to the second layer 112. The first layer 11 0 may be configured to reflect, refract, and/or otherwise alter the light radiation pattern emitted from the RBG LEDs. Therefore, the light emitted from the RBG LEDs may be pre-mixed before it passes to the second layer 112, which includes the light scattering material. As a result, the spatial color uniformity and mixing of red, blue, green and/or other lights can be improved by inclusion of the first layer 110, especially when compared to light emitting device that omit the first layer 110 and only have the second layer 112.

The first layer 110 and the second layer 112 may be any suitable translucent materials such as, for example, silicon, epoxy, or glass. The light scattering materials may be any organic or inorganic light scattering materials such as, for example, polymer powders or metal oxides. The light scattering materials may also be in any suitable shape such as spherical, pyramidal, or planar. In addition, they can be in any size. According to one embodiment, the particle size of them is less than or equal to 10 μm. However, any other suitable particle sizes may also be used.

According to one embodiment of the present invention, the first layer 110 and the second layer 112 do not have any wavelength conversion properties, configured to pass light through either the first layer 110 or the second layer 112, or both layers, maintaining the original wavelength of the light. The refractive index of the first layer 110 is greater than 1. According to another embodiment, the refractive index of the first layer 110 is less than the refractive index of the RBG LEDs, or other light emitting elements that may be used, and less than or equal to the refractive index of the second layer 112. The refractive index of the second layer 112 may also be less than the refractive index of the RBG LEDs, or other light emitting elements that may be used in the light emitting device 1 00.

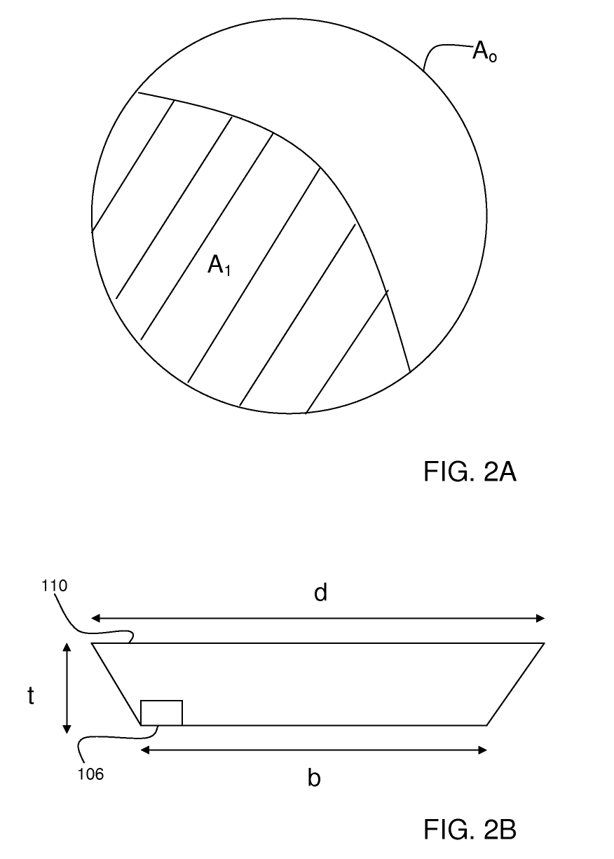

FIG. 2 is a cross sectional view of a light emitting device, in accordance with a second embodiment of the present invention. The light emitting device 200 includes a substrate 102, a light emitting element 106 bonded onto an optical cavity 103 formed in the substrate 102, a first layer 110 is filled into the optical cavity 103, disposed on top of or surrounding the light emitting element 106, and a second layer 112 including light scattering materials is formed over the first layer 110. Contact wires 114 may electrically connect the light emitting element 106 to metal contacts 116. A reflective coating 130 is coated onto the optical cavity 103 formed in the substrate 102. According to one embodiment of the present invention, the reflective coating 130 is configured to enhance and/or increase the reflection of light emitted from the light emitting element 106 before the light is emitted out through the first layer 110 and the second layer 112. For example, the reflective coating 130 can be silver (Ag) or aluminum (Al) coated, or coated with an alloy including silver, aluminum or other reflective material. The properties of the first layer 110 and the second layer 112 and the remaining components of the light emitting device for each of the embodiments shown and described with reference to FIGS. 2 to 5 are generally similar to those as described with reference to FIG. 1, unless otherwise stated.

FIG. 2A is a partial top view of the first layer of the light emitting device shown in FIG. 2, in accordance with a second embodiment of the present invention. The total surface area A₀ of the top surface of the first layer 110 is shown. A portion A₁ of total surface area A₀ is indicated by the surface line texturing. According to one embodiment, the light rays from any one of the light emitting elements passes through the portion A₁ of the total surface area of the first layer, and the portion A₁ is greater than or equal to approximately 80% of the total surface area A₀. Accordingly, a large portion of the light is evenly distributed prior to passing through the second layer 112. This condition should be effective in the condition either with or without reflective layer. According to one embodiment, more than half of the light is evenly distributed prior to passing through the second layer 112. According to another embodiment, more than 75% of the light is evenly distributed prior to passing through the second layer 112.

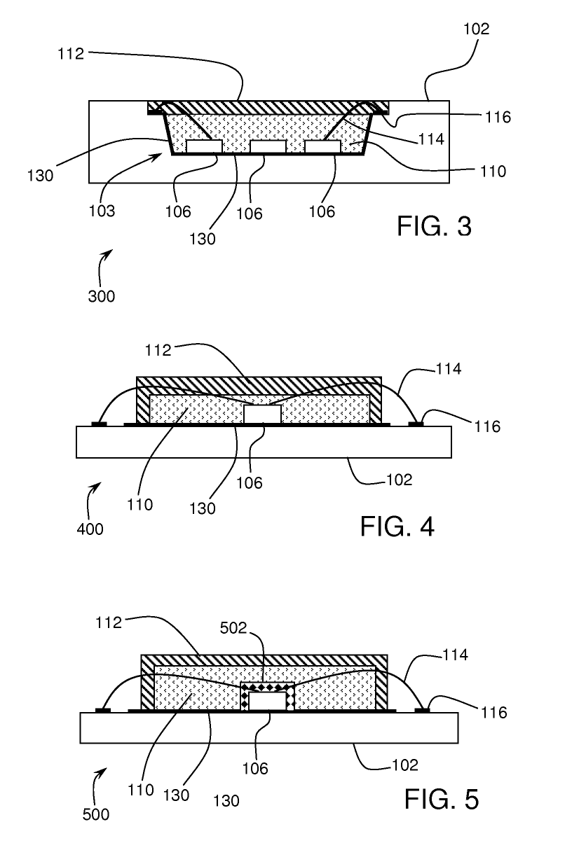

FIG. 2B is a partial, side cross sectional side view of the first layer shown in FIG. 2, in accordance with a second embodiment of the present invention. A height t, a top surface diameter d, and a base diameter b of the first layer 110 are shown. The base diameter b is also the base diameter of the cavity. According to one embodiment, the height t and the top surface diameter d are chosen such that d/t (d divided by t) is greater than or equal to zero and less than or equal to 25.5, or approximately 26, such that most of the light emitted from any of the light emitting element 106 is evenly distributed prior to passing through the second layer 112. According to another embodiment, d/b (d divided by b) is greater than or equal to 1 and less than or equal to 1.2 such that most of the light emitted from any one or more of the light emitting elements can be effectively reflected by the reflective coating 130 that is coated onto the optical cavity 103. While FIGS. 2A and 2B refer to FIG. 2, the above features may similarly apply to the embodiments shown in FIG. 1 and FIG. 3. Also, while the top view of the first layer 110 is shown as being circular, when the top surface of the first layer is not circular, b and d can be regarded as hydraulic diameters.

FIG. 3 is a cross sectional view of a light emitting device, in accordance with a third embodiment of the present invention. The light emitting device 300 is substantially similar to the light emitting device 200 as shown and described with reference to FIG. 2. However, the light emitting device 300 shown and illustrated with reference to FIG. 3 includes multiple light emitting elements 106. While the illustrated embodiment of the light emitting device 300 includes three light emitting elements 106, any number of the light emitting elements may be incorporated into the light emitting device 300 depending on the requirements of the particular implementation.

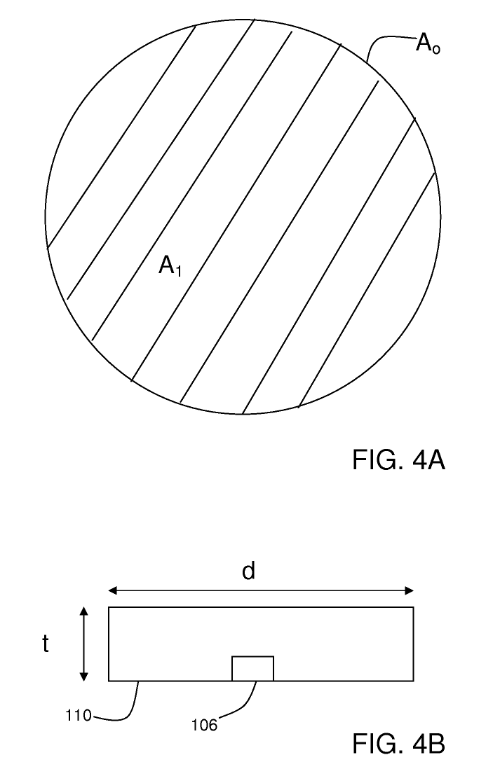

FIG. 4 is a cross sectional view of a light emitting device, in accordance with a fourth embodiment of the present invention. The light emitting device 400 is substantially similar to the light emitting device 200 shown and illustrated with reference to FIG. 2. However, in the fourth embodiment of the light emitting device 400, the substrate 102 does not have any optical cavity. Instead, the first layer 110 and the second layer 112 is formed on the substrate 102. A reflective coating 130 may be formed on top of the substrate 102, between the substrate 102 and the first and second layers 110, 112. The first layer 110 covers and surrounds the light emitting element 106, and the second layer 112, which includes light scattering materials, covers and surrounds the first layer 110. Contact wires 114 may electrically connect the light emitting element 106 to metal contacts 116. While one light emitting element 106 is shown, two or more light emitting elements may be used with the illustrated embodiment.

FIG. 4A is a partial top view of the first layer of the light emitting device shown in FIG. 3, in accordance with a fourth embodiment of the present invention. The total surface area A₀ of the top surface of the first layer 110 is shown, indicated by the circumference of the first layer 110. A portion A₁ of total surface area A₀ is indicated by the surface line texturing. According to one embodiment, the light rays from any one of the light emitting elements passes through the portion A₁ of the total surface area of the first layer, and the portion A₁ is equal to the total surface area A₀. Accordingly, A₁ completely covers A₀ and a large portion of the light is evenly distributed prior to passing through the second layer 112. This condition should be effective in the condition either with or without reflective layer.

FIG. 4B is a partial, side cross sectional side view of the first layer shown in FIG. 4, in accordance with a fourth embodiment of the present invention. A height t and a diameter d of the first layer 110 are shown. According to one embodiment, the height t and the top surface diameter d are chosen such that d/t (d divided by t) is greater than or equal to zero and less than or equal to 22.8, or approximately 23, such that most of the light emitted from any of the light emitting element 106 is evenly distributed prior to passing through the second layer 112. While FIGS. 4A and 4B refer to FIG. 4, the above features may similarly apply to the embodiments shown in FIG. 5. Also, while the top view of the first layer 110 is shown as being circular, when the top surface of the first layer is not circular, d can be regarded as a hydraulic diameter.

FIG. 5 is a partial cross sectional view of a light emitting device, in accordance with a fifth embodiment of the present invention. The fifth embodiment of the light emitting device 500 is substantially similar to the light emitting device 400 as shown and described with reference to FIG. 4. However, in the fifth embodiment of the present invention, the light emitting device 500 includes at least one fluorescence layer 502 surrounding and covering at least part of the light emitting element 106. The first layer 110 covers and surrounds the fluorescence layer 502. The fluorescence layer 502 may include one or more fluorescence materials such as yellow, red, blue or green light emitting phosphors. While one light emitting element 106 is shown, two or more light emitting elements may be used with the illustrated embodiment.

In the embodiments of the present invention, since the light rays emitted by the light emitting elements are pre-mixed in the first layer 110 prior to reaching the second layer 112, the amount of light scattering materials required in the second layer 112 can be reduced. In addition, the reduction in the amount of light scattering materials may thereby reduce the amount of optical loss and increase the intensity of the light emitted by the light emitting device.

While the invention has been particularly shown and described with reference to the illustrated embodiments, those skilled in the art will understand that changes in form and detail may be made without departing from the spirit and scope of the present invention. For example, while embodiments of the present invention are shown including the reflective coating 130, embodiments of the present invention may optionally include or omit the reflective coating 130 depending on the requirements of the particular implementation. Also, any suitable combinations of the various embodiments may also be used. Therefore, embodiments of the present invention may include a single light emitting element or multiple light emitting elements. While an LED is one example light emitting element suitable for use with embodiments of the present invention, other light emitting elements may also be used.

Accordingly, the above description is intended to provide example embodiments of the present invention, and the scope of the present invention is not to be limited by the specific examples provided.

What is claimed is:

1. A light emitting device comprising:
a substrate defining a cavity;
one or more light emitting elements bonded to the substrate, the one or more light emitting elements positioned in the cavity, the one or more light emitting elements configured to emit light;
at least one first layer covering the one or more light emitting elements, at least part of the at least one first layer within the cavity, the at least one first layer having an upper surface, wherein the at least one first layer has a refractive index less than the refractive index of the one or more light emitting elements; and
at least one second layer disposed on the at least one first layer, the at least one second layer including light scattering material, wherein the refractive index of the at least one second layer is less than the refractive index of the one or more light emitting elements, and the refractive index of the first layer is less than or equal to the refractive index of the second layer.

2. The light emitting device of claim 1, wherein the one or more light emitting elements are semiconductor-based devices.

3. The light emitting device of claim 1, wherein the one or more light emitting elements are organic light emitting diodes (OLED).

4. The light emitting device of claim 1, wherein the one or more light emitting elements emit one or more primary wavelengths.

5. The light emitting device of claim 1, further comprising one or more fluorescence layers covering the one or more light emitting elements, wherein the one or more fluorescence layers are configured to convert at least a portion of the light emitted by the one or more light emitting elements to light of having a different wavelength.

6. The light emitting device of claim 5, wherein the one or more fluorescence layers includes phosphors.

7. The light emitting device of claim 1, wherein the light scattering material includes a plurality of uniformly distributed particles to scatter the light emitted by the one or more light emitting elements.

8. The light emitting device of claim 1, wherein the particle size of light scattering material is smaller than or equal to 10 μm.

9. The light emitting device of claim 1, wherein each of the first layer and the second layer is insulating and transparent.

10. The light emitting device of claim 1, wherein the first layer is configured maintain the wavelength of the light passed through the first layer.

11. The light emitting device of claim 1, wherein the light from any one of the light emitting elements passes through a portion of the total surface area of an upper surface of the first layer, wherein the portion is greater than or equal to approximately 80% of the total surface area.

12. The light emitting device of claim 1, wherein a top surface diameter d of the first layer and a base diameter b of the first layer are configured such that d divided by b is greater than or equal to 1 and less than or equal to 1.2.

13. A light emitting device comprising:
a substrate;
one or more light emitting elements bonded onto the substrate;
at least one first layer covering the one or more light emitting elements on the substrate, the at least one first layer having an upper surface and side surfaces; and
at least one second layer covering the at least one first layer, the at least one second layer including light scattering material, wherein the refractive index of the at least one second layer is less than the refractive index of the one or more light emitting elements, and the refractive index of the first layer is less than or equal to the refractive index of the second layer.

14. The light emitting device of claim 13, wherein the one or more light emitting elements are semiconductor-based devices.

15. The light emitting device of claim 13, wherein the one or more light emitting elements are organic light emitting diodes (OLED).

16. The light emitting device of claim 13, wherein the one or more light emitting elements emit one or more primary wavelengths.

17. The light emitting device of claim 13, wherein the one or more light emitting elements are covered with one or more fluorescence layers, the one or more fluorescence layers configured to receive and convert at least a portion of the light emitted by the one or more light emitting elements to light of other wavelengths.

18. The light emitting device of claim 17, wherein the one or more fluorescence layers includes phosphors.

19. The light emitting device of claim 13, wherein the light scattering material includes a plurality of uniformly distributed particles configured to scatter light emitted by the one or more light emitting elements.

20. The light emitting device of claim 13, wherein the particle size of light scattering material is smaller than or equal to 10 μm.

21. The light emitting device of claim 13, wherein each of the first layer and second layer is insulating and transparent.

22. The light emitting device of claim 13, wherein the first layer is configured maintain the wavelength of the light passed through the first layer.

23. The light emitting device of claim 13, wherein the light from any one of the light emitting elements passes through the total surface area of an upper surface of the first layer.

24. The light emitting device of claim 13, wherein a height t of the first layer and a diameter d of the first layer are configured such that d divided by t is greater than or equal to zero and less than or equal to 22.8.
